(19) United States
(12) Patent Application Publication
(10) Pub. No.: US 2011/0076853 A1
(43) Pub. Date: Mar. 31, 2011

(54) Novel process method for post plasma etch treatment

(75) Inventor: Guomin Mao, San Jose, CA (US)

(73) Assignee: MagIC Technologies, Inc.

(21) Appl. No.: 12/586,786

(22) Filed: Sep. 28, 2009

(51) Int. Cl. H01L 21/3065

(52) U.S. Cl. 438/712; 257/E21.218

(57) ABSTRACT

A method of fabricating a wafer comprising MEMS devices comprises etching trenches or vias into the wafer using a deep reactive ion etching process wherein this process forms residual polymers on sidewalls of the trenches or vias. The wafer is exposed to a dry-cleaning process wherein residual polymers are removed. The dry-cleaning process comprises hot oven baking, combustion, or laser beam illumination.

### BACKGROUND OF THE INVENTION

(1) Field of the Invention

This invention is related to MEMS devices, and more particularly, to methods of removing residual polymers in the fabrication of MEMS devices.

(2) Description of the Related Art

Micro-electro-mechanical systems (MEMS), the smallest functional machines that can be manufactured currently, are made up of components ranging from a few micrometers to several millimeters in size. MEMS, a rapidly growing semiconductor field, have many important practical and potential commercial applications. There are a range of commercially available MEMS products including gyroscopes, pressure sensors, fluid regulators, optical switches, displays, mass data storage, biological sensors and chemical controllers.

MEMS can be fabricated using semiconductor integrated circuit technologies. The basic procedures capable of manufacturing silicon based MEMS devices are: ingot growth and slicing, film preparation or deposition, wafer bonding and polishing, photolithography masking and pattern etching, and residue removing with wet (or plasma) cleaning. One of the above steps is pattern etching which plays a critical role in MEMS manufacturing. There are two categories of etching processes: wet etching which uses chemical solutions to etch away unmasked patterns and form desired structures, and dry etching where the wafer is etched using reactive ion etching (RIE) or a vapor phase etchant.

In reactive ion etching (RIE), the substrate wafer is placed inside a reacting chamber in which several gases are introduced. The plasma is struck in the mixed gas atmosphere using a radio frequency (RF) power supplier, breaking the gas molecules into ions, free radicals, and other species. The ions and radicals can react with the surface material of the wafer, forming volatile gaseous molecules which are then pumped out of the etching chamber.

A special subclass of RIE is DRIE (deep reactive ion etching) which is mostly used in deep silicon etching. In this process, etch depths of hundreds of micrometers can be achieved with almost vertical sidewalls. To protect the sidewall from being attacked by the plasma, heavy polymer deposition on the sidewall is required during plasma etching. One of the current technologies is based on the so-called Bosch process where two different gas compositions are alternately introduced in the etching chamber: For example, SF₆ does isotropic etching and C₄F₈ provides polymer deposition or passivation. The C₄F₈ creates a polymer on the surface of the structure, and the second gas composition (SF₆ and O₂) physically sputters away the polymer on the bottom of the structure and then continues chemical DRIE. The sidewalls are protected by the built-up passivation from the SF₆ etching because the polymer dissolves very slowly in the chemical part of the etching. As a result, etching aspect ratios as high as 50 to 1 can be achieved. The DRIE process can be used to etch through a silicon substrate, and etching recipes can be tuned so that etch rates are several times to tens times higher than wet etching. The Bosch process is described in the paper “Milestones in deep reactive ion etching,” F. Laermer, A. Urban, Solid-State Sensors, Actuators and Microsystems, 2005. Digest of Technical Papers. TRANSDUCERS '05. The 13th International Conference on Vol. 2, 5-9 Jun. 2005 Pages 1118-1121.

The heavy polymer deposition resulting from the DRIE process cannot stick to the sidewall permanently and will adversely affect the performance of the device. Thus, it is critical to clean away this deposition after etching using some post treatments, usually a wet-cleaning process. U.S. Pat. No. 6,033,993 to Love, Jr. et al teaches using a rinse solution to remove polymers. While a regular wet-cleaning process can effectively remove the deposited polymer and other etching residuals for low aspect ratio or shallow structures (trenches, holes, circulars and so on), it is difficult to clean the high aspect ratio (HAR) structures with small etching feature sizes such as a few to tens micrometers.

The aspect ratio can be defined in two directions for trench-like structures: one is the etching depth (D) to etching width (W) aspect ratio (DWAR), and another is the etching length (L) to etching width (W) aspect ratio (LWAR) as shown in FIG. 1. While one only needs to be concerned about the DWAR (or simply HAR) for cleaning via-like structures as shown in FIG. 2, both DWAR and LWAR are critical for cleaning trench-like structures such as are shown in FIG. 1. In some MEMS designs, the shapes of the trenches are not straight. The trenches curve back and forth many times so that the total length L can reach a magnitude of millimeters; thus the LWAR could be very high. For example, L/W=500 for L=5 mm and W=10 um. For high DWAR and LWAR structures, the solution of the wet-cleaning chemicals may not easily flow in and out of the structures because of the liquid stiction and capillary effect. Since the dimensions D and L are much greater than W, the polymer pieces detached from the sidewalls during chemical solution cleaning are so large that they cannot move out of the small opening formed by the width W and will be jammed inside the structures. Sometimes, because of high values of DWAR and LWAR, only part of a polymer piece detaches from the sidewall while the remaining polymer still sticks on the sidewall. Thus, polymer pieces will stay inside or around the structures and cause problems later.

The situation could become worse during the drying process after using water to rinse the cleaning chemicals from the wafer. The heat applied to vaporize the trapped water will cause water to burst suddenly and the pressure created from releasing such a burst may break the thin sidewall and damage the MEMS devices which will cause low production yields. Furthermore, in wet-cleaning, to have a more effective cleaning, the liquid may be circulated with a fast-flowing current or agitated with strong ultrasonic waves, both of which could damage MEMS devices. Especially if the wafer contains already released moving components, the damage will be more severe. U.S. Pat. No. 7,122,797 (Guo et al) teaches DRIE followed by rinsing and spin-drying.

Of course, one might not clean the residue polymers and leave them alone. However, this will definitely reduce MEMS yield greatly and also cause reliability issues since the polymer will drop off from the sidewalls sooner or later and cause electric shorting or jam the path of the moving components. There are some other cleaning process methods not involving wet solutions; these use plasma to remove the residual polymers. U.S. Patent Applications 2007/0259471 to Li et al and 2008/0123089 to Seul et al teach oxygen plasma etches to remove residual polymers. However, these methods are mainly used for shallow structures with thin residual polymers. For the heavy passivation created in DRIE, they cannot clean the polymer well. Therefore, to increase yield and have reliable MEMS devices, it is strongly desired to find different ways to remove the undesired residual polymers that do not damage the MEMS devices.

### SUMMARY OF THE INVENTION

It is the primary objective of the present invention to use dry-cleaning process methods to remove the residual polymers created during DRIE etching.

It is another objective of the invention to use a high-enough temperature to eliminate or burn away the residual polymers created during DRIE etching to produce high MEMS fabrication yield and ensure reliable MEMS device performance.

Another objective of the invention is to provide dry-cleaning processes to eliminate or burn away residual polymers after DRIE etching wherein these dry-cleaning processes include hot oven baking, combustion, or laser beam processes.

In accordance with the objectives of the invention, a method of fabricating a wafer comprising MEMS devices is achieved. Trenches are etched into the wafer using a deep reactive ion etching process wherein this process forms residual polymers on sidewalls of the trenches. The wafer is exposed to a dry-cleaning process wherein residual polymers are removed. The dry-cleaning process comprises hot oven baking, combustion, or laser beam illumination.

### BRIEF DESCRIPTION OF THE DRAWINGS

It is the primary objective of the present invention to package a MEMS device in a vacuum cavity using a two-step solder reflow process.

FIG. 1 is a representation of trenches etched into a wafer.

FIG. 2 is a representation of vias etched into a wafer.

FIG. 3 is a cross-sectional representation of a hot oven apparatus in a first preferred embodiment of the present invention.

FIG. 4 is a cross-sectional representation of hot oven apparatus in a chamber in a first preferred embodiment of the present invention.

FIG. 5 is a cross-sectional representation of a combustion apparatus with a single fire flame nozzle in a second preferred embodiment of the present invention.

FIG. 6 is a cross-sectional representation of combustion apparatus with a plurality of fire flame nozzles in a second preferred embodiment of the present invention.

FIG. 7 is a cross-sectional representation of a laser illumination apparatus in atmosphere in a third preferred embodiment of the present invention.

FIG. 8 is a cross-sectional representation of a laser illumination apparatus in a chamber in a third preferred embodiment of the present invention.

FIG. 9 is a cross-sectional representation of a laser illumination apparatus with wafer cooling stage in a third preferred embodiment of the present invention.

FIG. 10 is a cross-sectional representation of a laser illumination apparatus with wafer heating stage in a third preferred embodiment of the present invention.

FIG. 11 is a cross-sectional representation of a wafer to be cleaned by the process of the present invention.

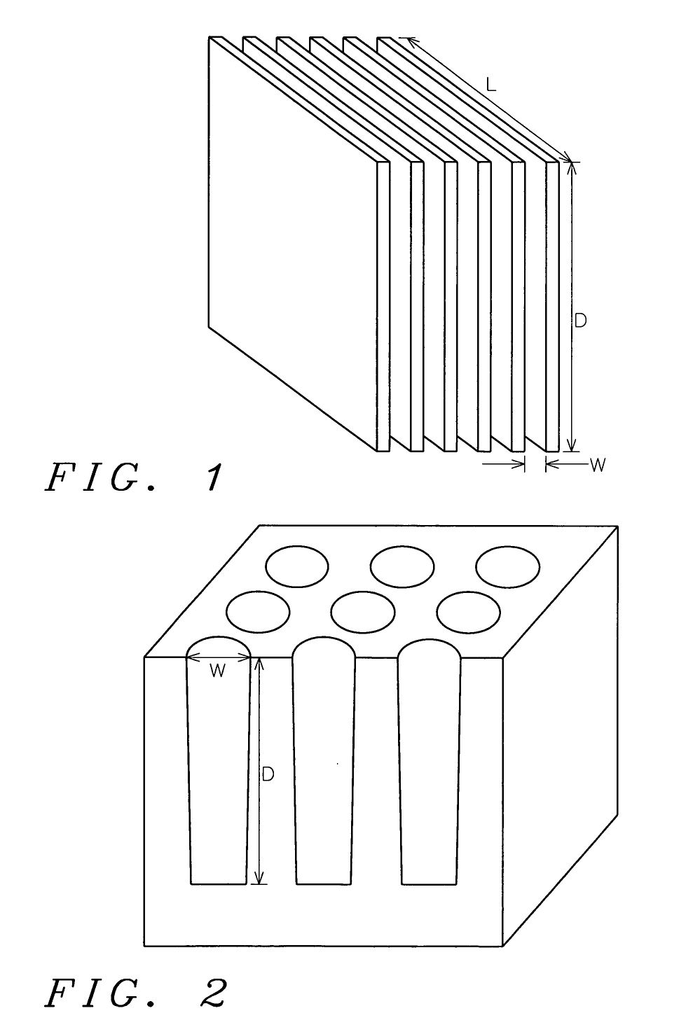

### DETAILED DESCRIPTION OF THE INVENTION

The present invention proposes three novel post-etch treatment methods that can be used to remove the residual polymers after DRIE etching. The methods are called post-etch dry-cleaning processes as opposed to the wet-cleaning processes usually used after plasma etching. In the dry-cleaning processes of the invention, after plasma etching, the wafers are placed in an environment such as a hot oven, a laser beam or a fire flame where the temperature is high enough that the polymers will be burned and decomposed into small molecules, then evaporated and pumped away. If not, then the polymers may be shrunken into very small pieces which either fall out by themselves or are blown out of the structure, or their sizes become so small and stick to sidewalls permanently that they would not interfere with the performance of the devices.

The traditional post-etch treatment method to clean the residues after plasma etching is so-called wet-cleaning in which the etched wafers are immersed in chemical liquids or mixture solutions such as EKC. The chemical solution might be heated to an elevated temperature and could also be stirred mechanically or agitated by ultrasonic waves to enhance cleaning ability. For low aspect ratio and large size structures, the wet-cleaning is an effective way to remove etching residues. However, for high DWAR and high LWAR structures with small etching feature widths from a few to tens of micrometers, the wet-cleaning may not be able to clean the structures well due to the stiction and capillary effect of the solution and the building up of large polymer residual pieces. In addition, to remove the water which is used to rinse off the chemicals, one may heat the wafer to vaporize the water; this could damage the structures with thin sidewalls, i.e. they could be broken by the suddenly increased pressure of water vapor trying to burst out of the narrow areas. In addition, the liquid current from mechanical stirring and the agitation by ultrasonic waves could also damage the devices. For these reasons, wet-cleaning applications are of limited effectiveness in some MEMS device fabrication processes.

In the novel post etch treatment processes of the present invention, dry-cleaning methods are introduced and are used to overcome the disadvantages of wet-cleaning methods. In the new methods of the invention, hot oven baking, combustion and laser beam illumination are used to clean away residual polymers. The hot gas flow, fire flame or laser beam can reach deep inside the structure easily without any resistance; hence, the sidewalls of the structures with great DWAR and LWAR are better cleaned. Since no liquids and solvents are used, the stiction and capillary effect no longer exist. Since the polymers are decomposed into small pieces or vaporized, the building up of residual polymer pieces that occurs in wet-cleaning is no longer an issue. In addition, the problem of component damage caused by the bursting of water evaporation at elevated temperature is resolved, and the possible damages introduced by mechanical agitation and ultrasonic waves are also eliminated. Moreover, because there are no chemical solutions used in the dry-cleaning processes of the invention, environmental contaminations are greatly reduced. The tiny amount of burning chemicals released in the dry-cleaning processes of the invention contrasts with a vast amount of waste produced in wet-cleaning. The invention also saves the cost of purchasing chemicals, maintaining wet-cleaning tools and performing chemical waste treatment.

The idea of using dry-cleaning methods to remove residual polymers created in plasma etching is based on the fact that the polymers can be “burned away” in an environment with high temperature such as in a hot oven, in a fire flame (such as from a hydrogen gas or a propone gas torch), or illuminated by high power laser beams. The large polymer chains will be decomposed into much smaller molecules which can be evaporated out of device structures at high temperature or blown off by gas flow in and out the structure. Some of the polymer chains may be partially decomposed and the left-over material may not be easily removed from the structures, but this material can be greatly shrunk into much smaller pieces which either might be blown out of the structures by flowing gases or stick permanently to the sidewalls of the structure thus not interfering with the performance of the devices. Several specific methods of dry-cleaning on the plasma etched wafers with residual polymers are presented here:

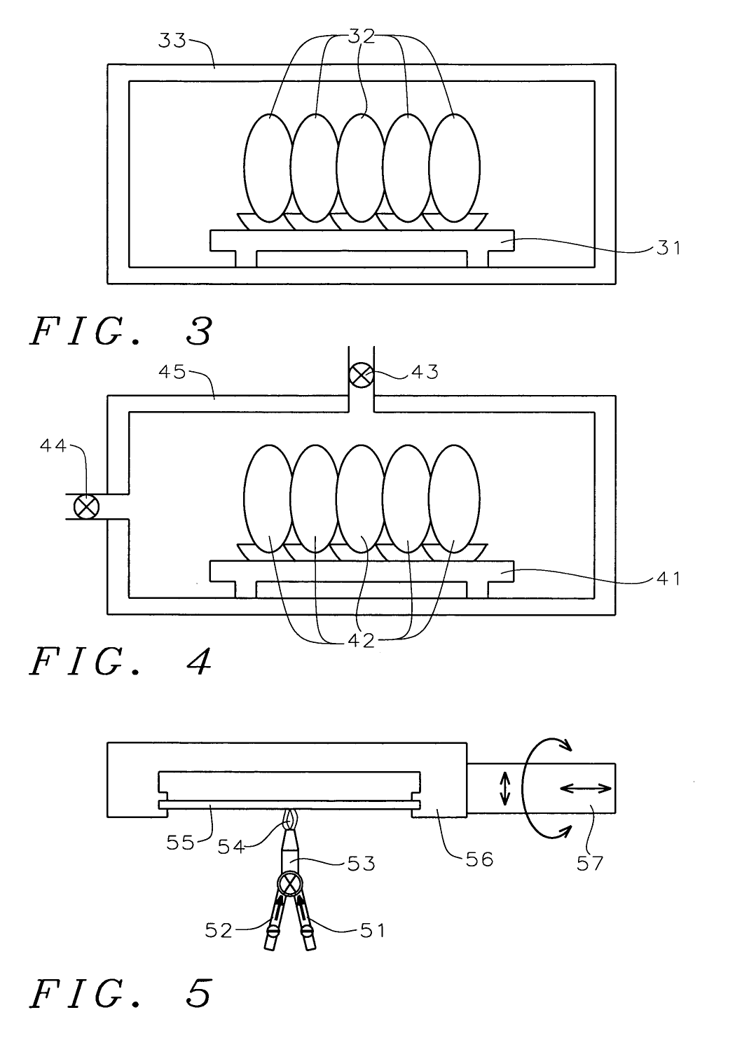

The first dry-cleaning method of the present invention is a hot oven baking method, as shown in FIG. 3. In this process method, the wafers 32 after plasma etch are placed in a metal or ceramic/glass (quartz) holder 31 which can resist high temperature and then put into a high temperature oven 33. The temperature of the oven should be set to such a value that it can easily burn the polymers but should not soften or melt the wafers (the silicon melting point is 1414° C.) so the MEMS devices and wafer holder would not be damaged. The exact temperature range and the length of the baking time should be tested according to the specific polymers. A different etching process might produce different polymers which may need different heating temperatures to burn away in a certain time period. Although the temperature plays a major role in the hot oven baking dry-cleaning process method, there are other factors that can assist the process to clean the wafer better in a shorter time:

During heating, pre-heated oxygen gas or air can be flowed into the oven to assist the burning of polymers, as shown in FIG. 4. Here, wafers 42 are placed in a metal or ceramic/glass (quartz) holder 41 which can resist high temperature and then put into a high temperature oven 45. This oven 45 has a gas inlet 43 and gas outlet 44. The oxygen gas or air is flowed into the oven 45 through the gas inlet 43. Actually, at high temperature, the oxygen will react more easily with polymers and decompose the polymer chains into smaller molecules faster, and the continuous flowing of oxygen gas will carry these decomposed molecules out of the structures through the gas outlet 44 by pumping the oven.

Although oxygen gas can decompose polymers, it will oxidize the wafer surface. However, in some cases, one may not want to have oxide on the wafer surface. To resolve this issue, one can use a vacuum hot oven or introduce an inert gas such as argon or helium into the oven chamber during baking. Since no oxygen is present, it is possible that the polymer chains may not be decomposed completely, and the remaining partially decomposed polymers will shrink to small pieces which either can be blown off the structure later by nitrogen or air guns or they may stick to the sidewall permanently. Since this is a high temperature process, these remaining pieces could strongly attach to the sidewalls and will not drop off later, and since they are very small, they will not interfere with the motion of the moving parts of the devices.

The vacuum sealed hot oven can have an operating pressure during heating below or above the atmospheric pressure. For a chamber pressure lower than atmospheric pressure, pumps should be employed to pump out the gases inside the chamber. For chamber pressures higher than atmospheric pressure, the amount of gas flow being injected in should be balanced by the amount of gas flow being pumped out in a such way that the chamber pressure will be well controlled, or the oven should be kept completely sealed after introducing high pressure. At high pressure, the oxygen may react with polymer chains more thoroughly and quickly. If the nitrogen or the mixture of nitrogen and oxygen are introduced into the oven, the nitrogen may also react with polymers at high pressure which may not occur at normal atmospheric pressure. This method is useful if oxide is not wanted on the wafer surface, but nitride is wanted on the wafer surface. For high pressure dry-cleaning, the oven must be specially designed to maintain the pressure during heating and to provide gas flow in to replace the reacted gas while also providing gas flow out to carry away the decomposed polymer molecules.

The second dry-cleaning method of the present invention is a combustion method. In this process method, the wafer 55, held by a metal or ceramic/glass (or quartz) holder 56, can be placed in a fire flame 54 such as that created by a hydrogen torch or propane flame, as shown in FIG. 5. For example, a hydrogen torch comprises oxygen gas flow 51 and hydrogen gas flow 52 into the fire flame nozzle 53. The wafer holder 56 may have a robot arm 57 that can perform both translation and rotation motions as indicated by the arrows on the arm. The residual polymers inside the structure should be instantaneously burned away in such a high temperature flame; hence this cleaning method is even faster than the hot oven baking method. When using a hydrogen torch, the advantage is that it is a clean process such that no residual carbon compounds from burning will contaminate the surface of the wafers; the disadvantage is that its very high temperature could potentially damage the devices. On the other hand, other fire flames such as from a propone torch may have a much lower temperature so as not to damage devices, but it may leave carbon contamination on the surface of the wafer. Therefore, one should select the type of fire flame accordingly. To protect the wafer from damage by the fire flame during the burning process, some cooling techniques and devices should be employed:

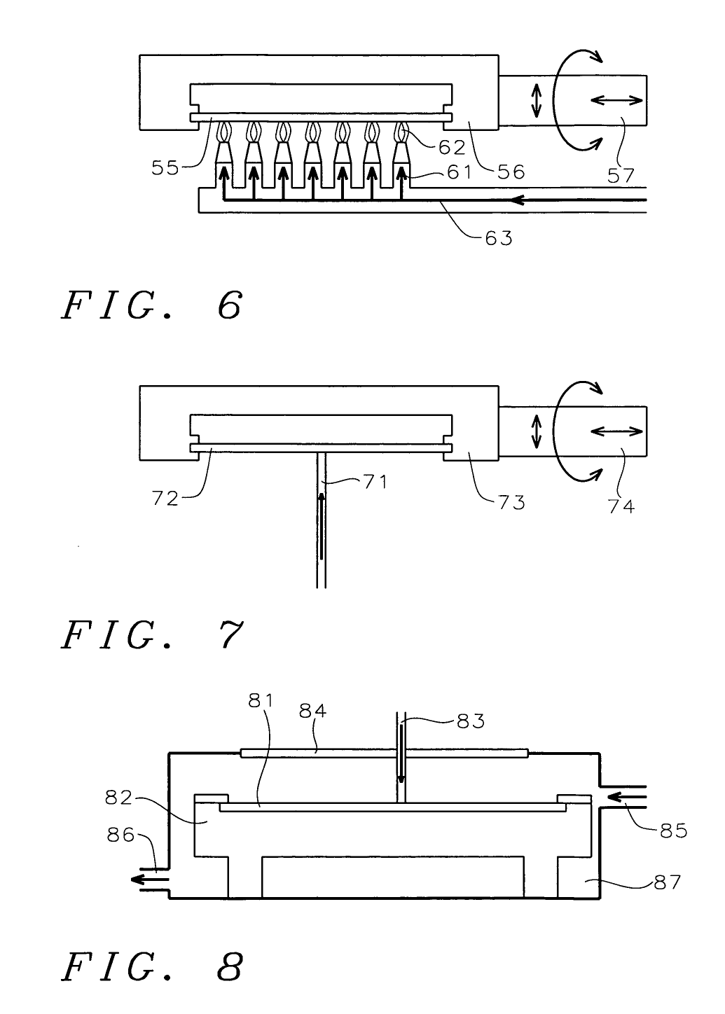

FIG. 6 illustrates an alternative embodiment in which an array of torches 62 is provided for large area burning. Gas flows 63 into the propane fire stove 61, for example, to result in multiple flames 62. The wafer should be moved into flame for a short time period if the whole wafer is immersed in fires from a plurality of flame nozzles as demonstrated in FIG. 6. The wafer should then be moved out of the flame. After waiting for a while to let the wafer cool down, the wafer should be placed in the flame again for a short time period. One may need to repeat this heating/cooling procedure several times until the residual polymers are burned away. The exact repeating times should be determined by testing.

One can use a small size flame to scan across the wafer so that only a small local part of the wafer experiences a short burning and the rest of the wafer is kept cool, as in the example shown in FIG. 5.

To prevent the wafer from becoming too hot during the process, one can place the wafer on a cooling stage. The wafer is chucked onto the stage which can flow cold gases (such as helium, argon, nitrogen or carbon dioxide) to cool down the wafer. Another way to cool the stage is by flowing coolant provided from a low temperature chiller; thus the wafer can be cooled down by contact with the stage.

The third dry-cleaning method of the present invention is laser beam illumination. One can use a high power laser beam to burn the residual polymers away. In this method, the wafers can be placed in a holder which is exposed to a laser beam in the atmosphere, as shown in FIG. 7, or in a chamber which can be in a vacuum or filled with gases, as shown in FIG. 8. FIG. 7 shows wafer 72 in wafer holder 73. Laser beams 71 illuminate the wafer. Robot arm 74 provides translation and rotation motion as indicated by the arrows on the arm so that the entire wafer can be exposed to the laser beam. In the alternative embodiment shown in FIG. 8, wafer 81 is placed into wafer holder 82. The wafer holder is placed in chamber 87, which can be in a vacuum or filled with gases. Gas inlet 85 and gas outlet 86 are shown. The laser beam 83 illuminates the wafer through the laser beam window 84. The window is large enough so that the laser beam can be manipulated to expose the entire wafer.

The energy of the laser beam should be controlled so that it will not damage the device but only burn the polymers. If the wafer is in a vacuum chamber or a chamber filled with non-reactive gases, the laser beam will only burn away the polymers and the wafer surface will not have oxide or nitride films formed on them. For this reason, the laser beam method has an obvious advantage over the hot oven and fire flame methods. However, it may be more costly and need more safety precautions.

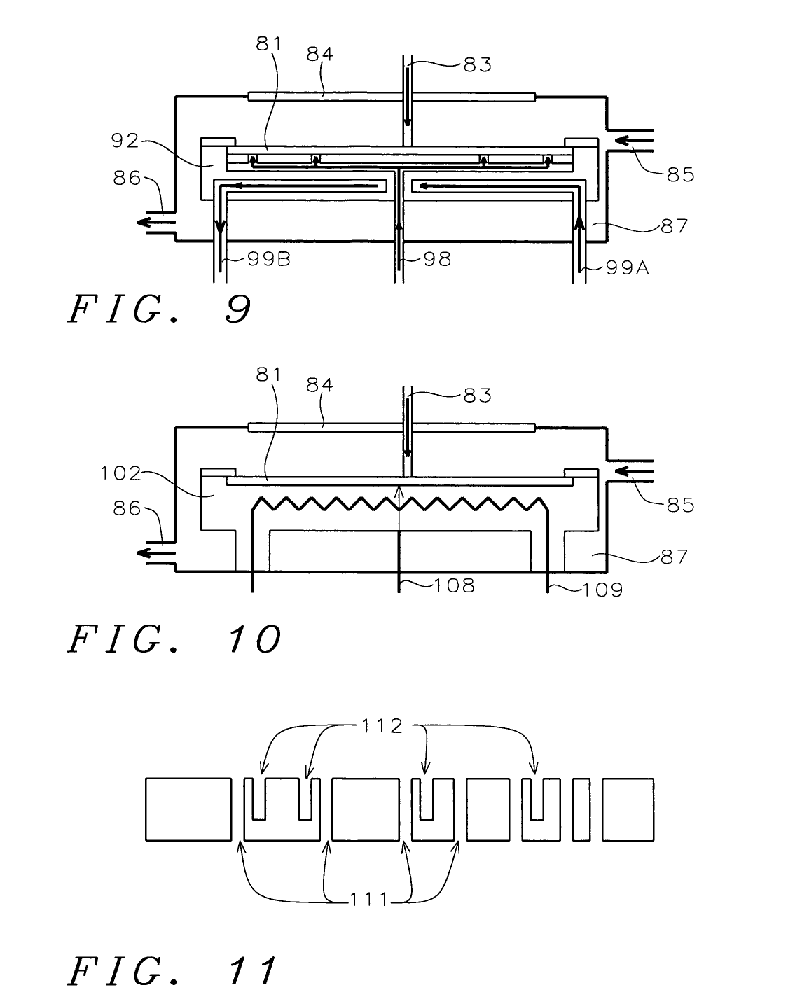

To prevent the wafer from becoming hot enough to damage the devices, the cooling methods described in the combustion dry-cleaning method can also be used during laser beam illumination. For a high power laser beam, one should cool the wafer to protect the devices. FIG. 9 illustrates a cooling option. The chamber 87 is the same as shown in FIG. 8. However, the wafer holder 92 includes coolant inlet 99A and coolant outlet 99B. Helium cooling gas, for example, flows through the wafer holder to cool the wafer.

For low power laser beams which may not provide enough energy to burn the residual polymers, one should use a heating stage to increase the wafer temperature to assist the laser beam in removing the polymers. FIG. 10 illustrates chamber 87 with a wafer holder 102 having a heater 109 and temperature sensor 108. The temperature of the heating stage 102 should be adjusted to such a value that it can assist the laser beam 83 in burning the polymer easily, but will not damage the devices. In addition, one can combine the hot oven method with the laser beam illumination method. That is, the hot oven must have a window to allow a laser beam to illuminate the wafers. Again, the temperature of the oven and power of the laser beam should be adjusted and tested to insure cleaning away the polymers without damaging the devices.

One can use more than one laser beam with different wavelengths to illuminate and burn away the residual polymers. The atomic bonds of the polymer chains may be easily broken with a certain wavelength light, and the other laser beams provide energy to heat up the decomposed molecules and vaporize them out of the structures. The oxygen gas and other gas mixture can flow in the structure to enhance the polymer decomposition, or the directional gas jet can be used to blow un-decomposed small polymer pieces out of the structure.

After the dry-cleaning treatment, there may be a thin oxide layer (or nitride layer, or carbon layer) on the wafer surface that needs to be removed. One can place the wafer in an oxide etch chamber to remove the oxide layer. In this plasma etch, a process having much less polymerization, such as CF₄/O₂ chemistry, should be used. Unlike the DRIE process, this oxide etch only produces very thin polymer veils (a few Angstroms to a few nanometers thick) after etch, which may be cleaned away in a dry-plasma stripper. In comparison with the heavy polymer deposition (hundreds to thousands of nanometers) in the DRIE etch, these veils are so much lighter that they will not pose any interference with the motion of the components of the MEMS devices.

Referring now to FIG. 11, a sample wafer is shown. 111 shows areas of the wafer that are “punched through;” that is, trenches or vias 111 extend all the way from a top side of the wafer to the bottom side of the wafer. 112 show trenches that do not extend all the way through the wafer. The direction of the surface of the wafer relative to the direction of gas flow, fire flame and laser beam may play a role in removing residual polymers. In the flame (or laser) case, if the wafer is punched through, then the flame (or laser) should be pointing downward while the wafer is face up to the flame (or laser) so that the decomposed polymer pieces can easily drop off the wafer. Otherwise, the flame should always point upwards and the wafer should face downwards.

The dry-cleaning processes of the present invention can effectively remove polymer residues in DWAR (or HAR) and LWAR structures after DRIE etching which could not be removed in a wet-cleaning process.

In addition, the dry-cleaning methods eliminate device damage caused by agitation or stiction which is often associated with wet-cleaning. The processes result in increased yield, lower operation and fabrication costs, lower material purchasing fees, higher performance devices and more environmentally-friendly waste handling.

Although the preferred embodiment of the present invention has been illustrated, and that form has been described in detail, it will be readily understood by those skilled in the art that various modifications may be made therein without departing from the spirit of the invention or from the scope of the appended claims.

What is claimed is:

1. A method of fabricating a wafer comprising:
providing a wafer comprising one or more MEMS devices;
etching trenches or vias into said wafer using a deep reactive ion etching process wherein said process forms residual polymers on sidewalls of said trenches or vias; and
thereafter exposing said wafer to a dry-cleaning process wherein said residual polymers are removed.

2. The method according to claim 1 wherein said dry-cleaning process comprises a hot oven baking method, a combustion method, or a laser beam illumination method.

3. The method according to claim 1 wherein said dry-cleaning process is performed in the atmosphere or in an isolated chamber.

4. The method according to claim 3 wherein said dry-cleaning process is performed in an isolated chamber in a vacuum and further comprising flowing gases into said chamber.

5. The method according to claim 4 wherein said gases comprise oxygen gases, inert gases, nitrogen gases, oxygen and nitrogen mixed gases, or a mixture of oxygen, nitrogen, and inert gases.

6. The method according to claim 5 wherein said inert gases comprise helium, argon, neon, or carbon dioxide.

7. The method according to claim 2 wherein said dry-cleaning process is performed in an isolated chamber wherein:
pressure within said chamber is less than, equal to, or greater than atmospheric pressure; and
wherein said chamber is vacuum sealed with no gas flow in or out of the chamber during said dry cleaning process, or wherein gases continuously flow in and out of said chamber during said dry-cleaning process, or wherein said gases are flowed in and out of said chamber alternately during said dry-cleaning process.

8. The method according to claim 1 wherein during said dry-cleaning, said wafer is placed in a metal, glass, quartz, or ceramic holder, or said wafer is placed on a cooling stage, or said wafer is placed on a heating stage.

9. The method according to claim 1 further comprising cleaning said wafer with air or nitrogen gas flow after said dry-cleaning process.

10. The method according to claim 2 wherein said dry-cleaning process is a combination of laser beam illumination and hot oven baking.

11. The method according to claim 2 wherein said dry-cleaning process is a laser beam illumination process and wherein several laser beams having different wavelengths are used.

12. A method of fabricating a wafer comprising:
etching trenches or vias into said wafer using a deep reactive ion etching process wherein said process forms residual polymers on sidewalls of said trenches or vias; and
thereafter exposing said wafer to a dry-cleaning process wherein said residual polymers are removed wherein said dry-cleaning process comprises a hot oven baking method, a combustion method, or a laser beam illumination method.

13. The method according to claim 12 wherein said dry-cleaning process is performed in the atmosphere or in an isolated chamber.

14. The method according to claim 13 wherein said dry-cleaning process is performed in an isolated chamber in a vacuum and further comprising flowing gases into said chamber.

15. The method according to claim 14 wherein said gases comprise oxygen gases, inert gases, nitrogen gases, oxygen and nitrogen mixed gases, or a mixture of oxygen, nitrogen, and inert gases wherein said inert gases comprise helium, argon, neon, or carbon dioxide.

16. The method according to claim 12 wherein said dry-cleaning process is performed in an isolated chamber wherein:
pressure within said chamber is less than, equal to, or greater than atmospheric pressure; and
wherein said chamber is vacuum sealed with no gas flow in or out of the chamber during said dry cleaning process, or wherein gases continuously flow in and out of said chamber during said dry-cleaning process, or wherein said gases are flowed in and out of said chamber alternately during said dry-cleaning process.

17. The method according to claim 12 wherein during said dry-cleaning, said wafer is placed in a metal, glass, quartz, or ceramic holder, or said wafer is placed on a cooling stage, or said wafer is placed on a heating stage.

18. The method according to claim 12 further comprising cleaning said wafer with air or nitrogen gas flow after said dry-cleaning process.

19. The method according to claim 12 wherein said dry-cleaning process is a combination of laser beam illumination and hot oven baking.

20. The method according to claim 12 wherein said dry-cleaning process is a laser beam illumination process and wherein several laser beams having different wavelengths are used.
